(19) United States
(12) Patent Application Publication
(10) Pub. No.: US 2025/0113449 A1
(43) Pub. Date: Apr. 3, 2025

(54) SAFETY LATCH FOR SERVER SLIDES

(71) Applicant: Asia Pacific CIS (Wuxi) Co., Ltd., Wuxi (CN)

(72) Inventor: Dafei Zou, Wuxi (CN)

(21) Appl. No.: 18/894,308

(22) Filed: Sep. 24, 2024

(30) Foreign Application Priority Data
Sep. 28, 2023 (CN) 202322666476.6

(51) Int. Cl. H05K 5/02; H05K 7/14

(52) U.S. Cl. CPC H05K 5/0221; H05K 7/1489

(57) ABSTRACT

A server slide can include a first rail that is slidable relative to a second rail. A rotatable locking member can be supported on the first rail to engage a protrusion extending from the second rail. The server slide can further include a slide release translatable along the first rail from a locked position to rotate the locking member and selectively disengage the locking member from the protrusion. A latch rotatable relative to a home position may permit translation of the slide release from a first position to a second position. The slide release may translate from the locked position into the first position to rotate the locking member and permit unidirectional movement of the first rail relative to the second rail and translate from the first position to the second position to rotate the locking member and permit bidirectional movement of the first rail relative to the second rail.

### CROSS-REFERENCE TO RELATED APPLICATION

This application claims priority to Chinese Utility Model application No. 202322666476.6, filed Sep. 28, 2023, which is herein incorporated by reference in its entirety.

### BACKGROUND

Slides (e.g., server rack slides) may enable a user to selectively access a server chassis secured within a server rack. For example, the slides may support the server chassis and enable a user to expand the slides (e.g., telescope slides away from server rack) to access the server chassis (e.g., for maintenance). However, overexpansion of the slides may result in accidental removal of the server chassis from the server rack, which may result in unintended server downtime or costs.

### SUMMARY

Some embodiments of the invention provide a server slide assembly configured to mitigate the risk of accidental removal of a server chassis from a server rack. The server slide can include a first rail having a rotatable locking member configured to engage a protrusion extending from a second rail. The server slide can further include a slide release configured to rotate the locking member to selectively disengage the protrusion. In some examples, the server slide can include a latch configured to selectively enable actuation of the slide release. In one example, actuation of the slide release into a first position is configured to enable unidirectional movement of the first rail. In another example, actuation of the slide release into a second position is configured to enable bidirectional movement of the first rail.

Some embodiments of the invention provide a server slide having a first rail and a second rail that slidably receives the first rail. A rotatable locking member can be supported on the first rail to engage a protrusion extending from the second rail. The server slide can further include a slide release translatable along the first rail from a locked position to rotate the locking member and selectively disengage the locking member from the protrusion. A latch rotatable relative to a home position may permit translation of the slide release from a first position to a second position. The slide release may translate from the locked position into the first position to rotate the locking member and permit unidirectional movement of the first rail relative to the second rail and translate from the first position to the second position to rotate the locking member and permit bidirectional movement of the first rail relative to the second rail.

Some embodiments of the invention provide a method of operating a server slide assembly. The method can include translating a slide release along a first rail from a locked position to a first position, to partially release a locking member from engagement with a protrusion on a second rail, to permit movement of the first rail in a first direction relative to the second rail, rotating a latch away from a home position to permit movement of the slide release into a second position, and with the latch rotated away from the home position, translating the slide release along the first rail from the locked position or the first position into a second position, to permit selective movement of the first rail relative to the second rail in either of the first direction or a second direction opposite the first direction.

Some embodiments of the invention provide a server slide including a first rail, a second rail that slidably receives the first rail, a locking member rotatably supported on the first rail to engage a protrusion extending from a second rail, a slide release that is translatable along the first rail to rotate the locking member and selectively disengage the locking member from the protrusion, and a latch rotatable relative to a home position to selectively permit translation of the slide release from a first position to a second position. The latch can include a body defining a nose at a first end to contact an end of the slide release when the slide release is in the first position and the latch is in the home position, a biasing element secured between a second end of the body and the first rail to bias the latch into the home position. The slide release can rotate the locking member to permit unidirectional movement of the first rail relative to the second rail when in the first position. The slide release can rotate the locking member to permit bidirectional movement of the first rail relative to the second rail when in the second position.

### BRIEF DESCRIPTION OF THE DRAWINGS

The accompanying drawings, which are incorporated in and form a part of this specification, illustrate embodiments of the invention and, together with the description, serve to explain the principles of embodiments of the invention:

FIG. 1 is a side view of a server slide assembly including a latch assembly according to aspects of the present disclosure.

FIG. 2 is a side view of a rotatable locking member for use with the server slide assembly of FIG. 1.

FIG. 3 is a side view of the latch assembly of FIG. 1.

FIG. 4 is a partial cross-sectional view of the server slide assembly of FIG. 1 with a slide release in a locked position.

FIG. 5 is a partial cross-sectional view of the server slide assembly of FIG. 1 with the slide release in a first position and a latch of the latch assembly in a home position.

FIG. 6 is a partial cross-sectional view of the rotatable locking member with the slide release in the first position of FIG. 5.

FIG. 7 is a side view of the latch assembly with the latch in the home position.

FIG. 8 is a partial cross-sectional view of the server slide assembly of FIG. 1 with the slide release in a second position.

FIG. 9 is a partial cross-sectional view of the rotatable locking member with the slide release in the second position.

FIG. 10 is a side view of the latch with the latch assembly with the slide release in the second position.

### DETAILED DESCRIPTION

The following discussion is presented to enable a person skilled in the art to make and use embodiments of the invention. Given the benefit of this disclosure, various modifications to the illustrated embodiments will be readily apparent to those skilled in the art, and the principles herein can be applied to other embodiments and applications without departing from embodiments of the invention. Thus, embodiments of the invention are not intended to be limited to embodiments shown, but are to be accorded the widest scope consistent with the principles and features disclosed herein.

The following detailed description is to be read with reference to the figures, in which like elements in different figures have like reference numerals. The figures, which are not necessarily to scale, depict selected embodiments and are not intended to limit the scope of embodiments of the invention. Skilled artisans will recognize the examples provided herein have many useful alternatives and fall within the scope of embodiments of the invention.

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

In one example, a server slide assembly may include a latch (i.e., a safety latch) configured to prevent accidental removal of a portion of the server slide. In one example, the server slide may include a first rail nested within a second rail. In some examples, the first rail is configured to telescope within the second rail to expand or contract an overall length of the server slide. In one example, the latch is configured to prevent the accidental removal of the first rail from within the second rail. For example, the latch is configured to prevent the disengagement of a slide lock (e.g., a rotatable pawl) positioned on the first rail.

The rotatable locking member may be engaged with a corresponding angled (e.g., chamfered) end of a slide release. The slide release may be configured to actuate laterally (e.g., to translate along the first rail) to disengage the locking member from a protrusion extending from the second rail. The protrusion is configured to nest within a cutout of the locking member when the locking member is in a first position to prevent movement (e.g., telescoping) of the first rail. However, when a user actuates the slide release into a first position (e.g., via a first handle), the end of the slide release generates rotation in the member, which partially disengages the cutout from the protrusion. In this configuration, the first rail is able to slide into (e.g., telescope into) the second rail. However, outward movement (e.g., extension of first rail) is still prevented via the protrusion. Thus, in this configuration, the first rail may move unidirectionally.

To fully release the protrusion from the cutout, the user can further actuate the slide release (e.g., using a second handle) while also (e.g., simultaneously) rotating the latch, which actuates the slide release into a second position. In particular, the rotation of the latch enables additional lateral displacement of the slide release, which further rotates the locking member and releases the protrusion from the cutout. Thus, the first rail may be telescoped inwards, outwards, or removed from the second rail, if desired. Thus, in this configuration, the first rail may move bidirectionally. In one example, the slide release may include a biasing element (e.g., spring) configured to automatically return the slide release to a locked position upon release. In another example, the latch may include a biasing element (e.g., a spring) configured to bias the latch into a home position, which prevents actuation of the slide release into the second position (e.g., contacts the slide release to block movement past the first position).

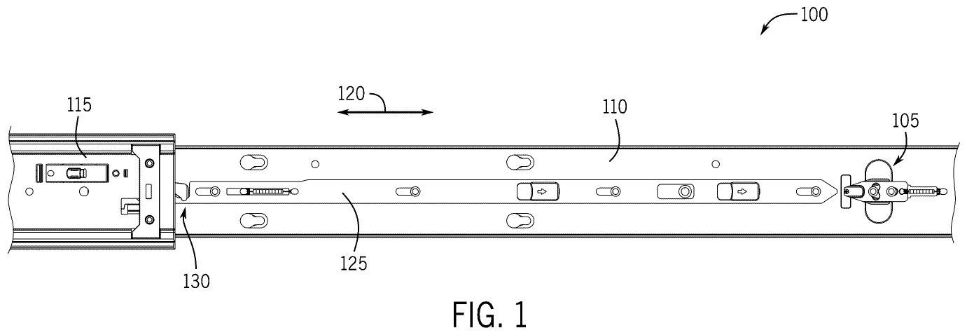

FIG. 1 illustrates an example of a slide assembly 100. The slide assembly 100 may include a latch 105 configured to prevent inadvertent removal of a first rail 110 from a second rail 115. In one example, the first rail 110 is nested within the second rail 115 and configured to telescope relative to (e.g., slide into and out of) the second rail 115 as shown by arrow 120. The telescopic nature of the slide assembly 100 enables a user to compress the overall dimensions of the slide assembly 100 to save space. Additionally, the telescopic nature of the slide assembly 100 enables a user to expand the overall dimensions of the slide assembly 100 to enable a user to gain access to a server or other component held by the slide assembly 100. Thus, a user may selectively expand the slide assembly 100 to perform maintenance or removal/replacement of the server or other component. Correspondingly, when access to the server or other component is not needed, the user may compress the slide assembly 100 to save overall space.

In one example, the first rail 110 may include a slide release 125 secured to the first rail 110. The slide release 125 may be configured to selectively engage or disengage a slide lock in the form of a rotatable locking member 130 configured to selectively prevent telescopic movement of the first rail 110. For example, the slide release 125 may be actuated into one or more positions configured to lock, partially unlock, or fully unlock relative movement of the first rail 110 with respect to the second rail 115. In one particular example, the slide release 125 may be actuated between a locked position where telescopic movement of the first rail 110 is locked, a first (partially unlocked) position where movement of the first rail 110 is unidirectionally unlocked (e.g., movement in one direction is permitted, but not in another direction), and a second (fully unlocked) position where bidirectional movement of the slide assembly 100 is permitted.

In one example, the latch 105 is configured to prevent inadvertent actuation of the slide release 125 into the fully unlocked position. The latch 105 may block actuation of the slide release 125 beyond a predetermined position, which corresponds to the partially unlocked position noted above. Thus, a user may actuate the latch 105 out of the path of the slide release 125 to enable the slide release 125 to reach the fully unlocked position and enable bidirectional telescopic movement of the first rail 110.

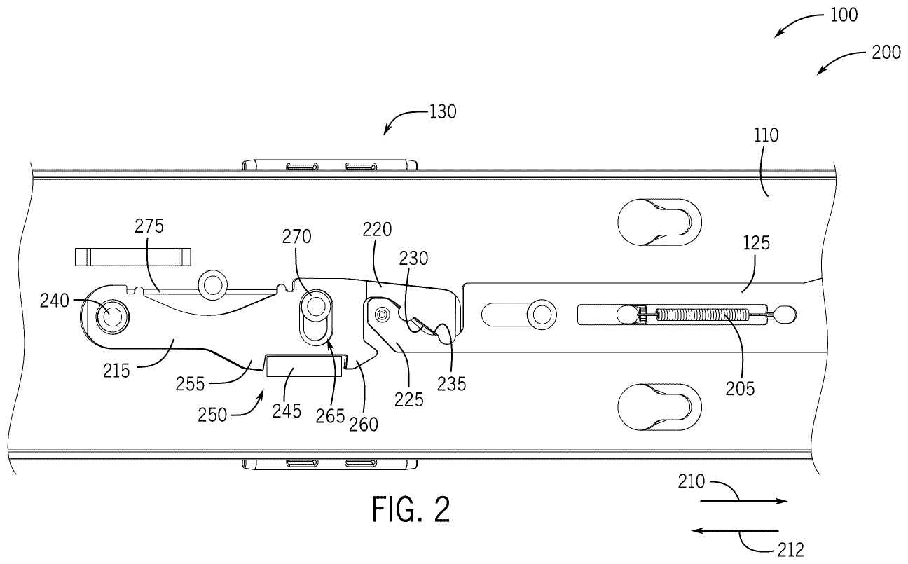

FIG. 2 shows an example of the slide assembly 100 with the slide release 125 in a locked position 200. In the locked position 200 the locking member 130 is oriented by the slide release 125 to prevent movement of the first rail 110. As shown, the slide release 125 may include a biasing element 205 (e.g., a spring or other resilient material) arranged between the slide release 125 and the first rail 110. The biasing element 205 may be configured to bias the slide release 125 into the locked position when no force is applied to the slide release 125. Put differently, the biasing element 205 may bias the slide release 125 into particular alignment (e.g., engagement) with the member 130. As described previously, the slide release 125 may be actuated in the direction shown by arrow 210 to selectively unlock movement of the first rail 110. Correspondingly, to unlock movement of the first rail 110 a user overcomes the biasing force applied by the biasing element 205, which operates in the direction shown by arrow 212.

The locking member 130 may include a body 215 with a first end defining a hook 220 configured to interact with an angled end 225 of the slide release 125. In one example, the hook 220 and the angled end 225 may each include corresponding planar faces 230, 235. The planar faces 230, 235 may define a predetermined angle or chamfer to enable slidable relation between the member 130 and the slide release 125, to correspond to a predetermined amount of rotation of the member 130. The member 130 may further include a fastener 240 securing the member 130 to the first rail 110. In one example, the fastener 240 may serve as a pivot point for the member 130. In some examples, an additional fastener 270 may be positioned adjacent a center of the member 130. The fastener 270 may be configured to slide within a channel 265 defined by the body 215 of the member 130 to prevent over-actuation of the member 130 (e.g., over-rotation of the member 130). Correspondingly, the member 130 may include a biasing element 275 configured to bias the member 130 into contact with the angled end 225 of the slide release 125. Thus, actuation of the member 130, via the slide release 125, may overcome the biasing force of the biasing element 275. In another example, the fastener 240 and the fastener 270 may trade positions. For example, the fastener 240 may be positioned adjacent a center of the member 130 while the fastener 270, and corresponding channel 265, may be positioned at an end of the body 215 opposite the hook 220.

To lock relative movement between the first rail 110 and the second rail 115, the second rail 115 includes a protrusion 245, which extends from the second rail 115 towards the first rail 110. In one example, the protrusion 245 is configured to engage with a cutout 250 defined by the body 215 of the member 130. For example, the protrusion 245 may nest within the cutout 250 of the member 130 when the slide release 125 is in the locked position to prevent telescopic movement of the first rail 110. In one example, the cutout 250 may be further defined or bounded by a first locking tab 255 and a second locking tab 260. The locking tabs 255, 260 may be configured to release or disengage from the protrusion 245 (e.g., release the protrusion 245 from the cutout 250) based on a position of the slide release 125, which corresponds to a rotational position of the member 130.

In one example, the second locking tab 260 may disengage from the protrusion 245 when the slide release 125 is in the partially unlocked position to enable movement of the first rail 110 in the direction shown by arrow 212. However, the first locking tab 255 may not disengage from the protrusion 245 when the slide release 125 is in the partially unlocked position to prevent movement of the first rail 110 in the direction shown by arrow 210. Correspondingly, the first locking tab 255 and the second locking tab 260 may both disengage from the protrusion 245 when the slide release 125 is in the fully unlocked position to enable movement of the first rail 110 in the direction shown by both arrow 210 and arrow 212. Put differently, the second locking tab 260 may disengage from the protrusion 245 at a lower angle of rotation of the member 130, relative to the locked position, than does the first locking tab 255.

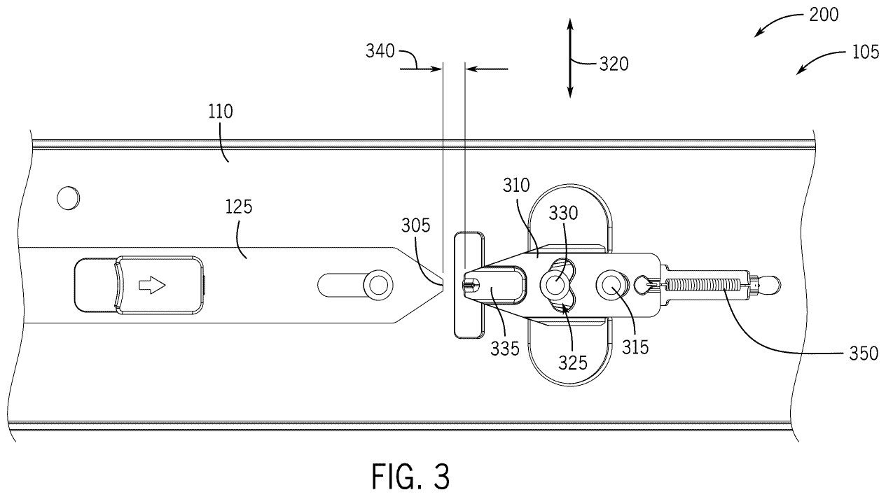

Turning to FIG. 3, an example of the latch 105 is shown with the slide release 125 in the locked position 200. In the locked position 200, a tip 305 of the slide release 125 may be separated from (i.e., spaced apart from) a nose 335 of the latch 105 defining a gap 340. Put differently, the slide release 125 may be free from contact with the latch 105 and thus not restricted by the latch relative to translational movement.

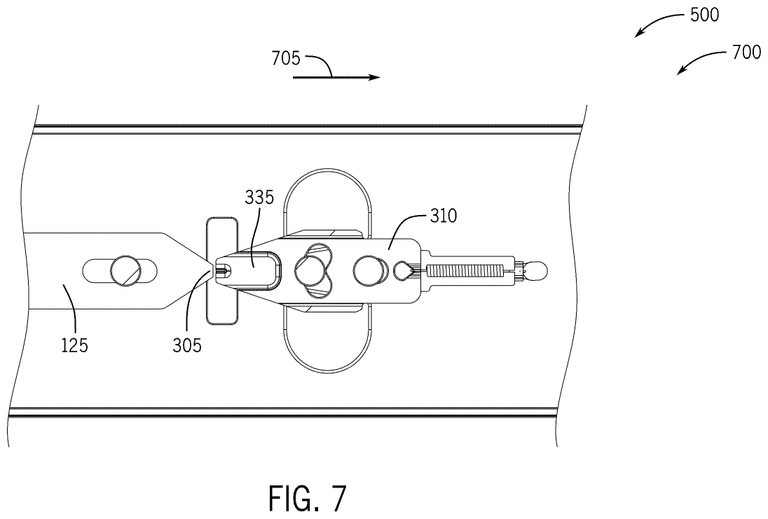

As shown, the latch 105 may include a body 310 secured to the first rail 110 via a fastener 315, which corresponding serves as a pivot point for the latch 105. The body 310 may further define a fastener 330 slidably located within a channel 325. The fastener 330 and channel 325 are configured to prevent over-actuation (e.g., over-rotation) of the latch 105, and may be differently located in some examples (e.g., reversed in lateral location). In one example, the latch 105 may include a biasing element 350 (e.g., a spring or other resilient material) secured between the body 310 and the first rail 110. The biasing element 350 may be configured to bias the latch 105 into a home position 700 (see FIG. 7) in which the nose 335 of the latch 105 is aligned with the slide release 125 along the translational direction of the slide release 125.

Thus, for example, the biasing element 350 may biasingly orient latch 105 the prevent a user from moving the slide release 125 into the fully unlocked position, which prevents inadvertent or accidental removal of the first rail 110 from the second rail 115. Correspondingly, to move the slide release 125 to the fully unlocked position, the latch 150 may need to be first actuated (e.g., rotated) out of the path of the slide release 125 In one example, a user may actuate the latch 105 in the direction shown by arrow 320 (e.g., rotate the latch 105 about the pivot point formed by fastener 315). In one example, a user may actuate the latch 105 against the biasing force of the biasing element 350 to remove the nose 335 from the path of the slide release 125 and thereby enable the slide release 125 to translate along the rail 110 to the fully unlocked position.

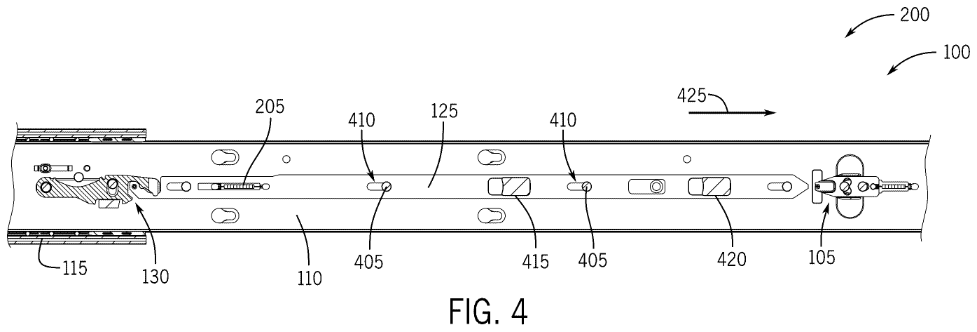

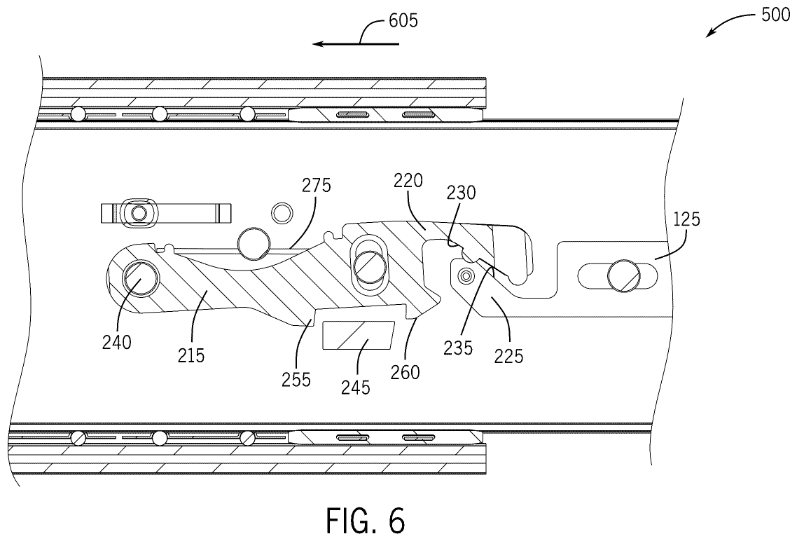

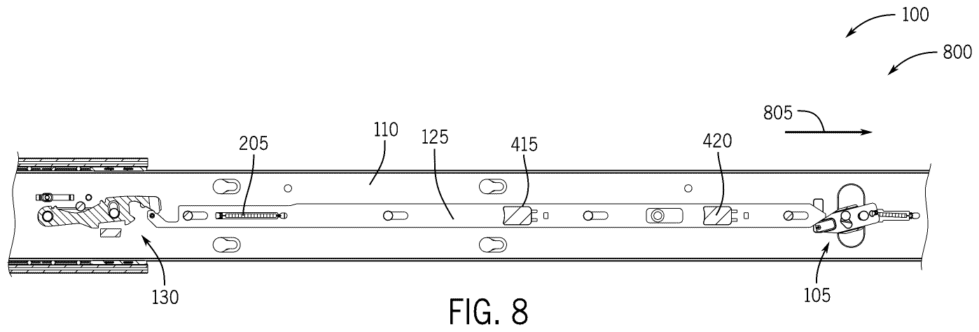

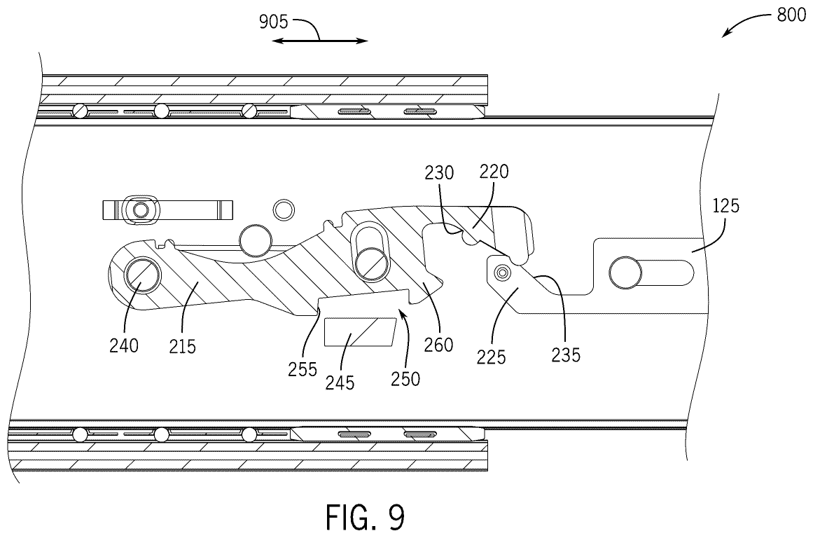

FIGS. 4-10 show examples of the slide assembly 100 during use with the slide release 125 in each of the locked position, partially unlocked position, and the fully unlocked position. As mentioned previously, when the slide release 125 is in the locked position 200 the protrusion 245 is held within the cutout 250 (e.g., between the first locking tab 255 and the second locking tab 260) to lock relative movement of the first rail 110 with respect to the second rail 115. To guide lateral movement of the slide release 125, the slide release 125 may include one or more channels 410 configured to interact with one or more fasteners 405, which enable lateral movement of the slide release 125 while simultaneously preventing vertical displacement of the slide release 125.

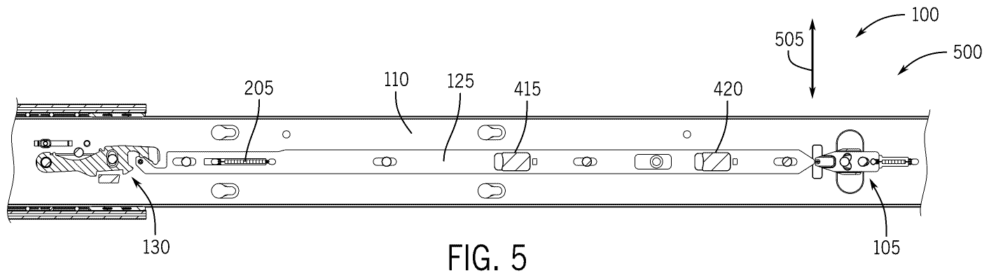

In one example, the slide release 125 may further include a first handle 415 and a second handle 420 configured to enable a user to actuate the slide release 125 in the direction shown by arrow 425. In one example, to actuate the slide release 125 between the locked position 200 and a first (partially unlocked) position 500 (shown in FIG. 5) a user grasps either the first handle 415 or the second handle 420 and applies a force to the slide release 125 in the direction shown by arrow 425. As a result, the planar faces 230, 235 of the hook 220 and the angled end 225 slide against one another, which generates a corresponding rotation in the member 130 about the fastener 240. Thus, a predetermined amount of lateral displacement of the slide release 125 can correspond to a predetermined amount of rotation of the member 130 to partially or fully disengage the protrusion 245 from the cutout 250. In one example, moving the slide release 125 to the first position 500 generates rotation of the member 130 sufficient to disengage the second locking tab 260 from the protrusion 245, which enables unidirectional movement of the first rail 110 with respect to the second rail 115 (e.g., in the direction shown by arrow 605) but prevents movement of the first rail 110 in an extension direction.

In the first position 500, the slide release 125 may be laterally displaced from the locked position so that the tip 305 of the slide release 125 contacts the nose 335 of the body 310. Thus, the gap 340 between the tip 305 and the nose 335 is reduced or removed when the slide release 125 is in the first position 500 (shown in FIG. 7). In one example, the slide release 125 is prevented from further lateral displacement in the direction shown by arrow 705 via the latch 105. Thus, the slide release 125 may not be movable from the first position 500 to a second (fully unlocked) position 800 until the latch 105 is repositioned out of the path of the slide release 125.

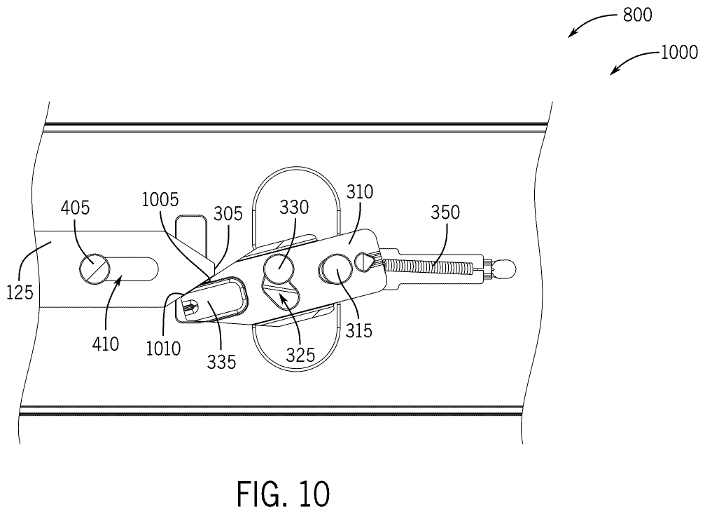

In one example, the latch 105 may be actuated (e.g., rotated) in the directions shown by arrow 505 to a disengaged position 1000 (shown in FIG. 10). In the disengaged position 1000, the nose 335 of the latch 105 is positioned out of the path of the slide release 125. As a result, the slide release 125 may continue to laterally displace into the second position 800.

In one example, as the nose 335 of the latch 105 moves out of the path of the tip 305 of the slide release 125 the user simultaneously actuates the slide release 125 via the first or second handles 415, 420. Or a user may first move the latch 105 and then actuate the slide release 125. As the user moves the slide release 125 towards the latch 105, an angled face 1005 of the slide release 125 can contact an angled face 1010 of the latch 105, which can enable the slide release 125 to continue to slide along the latch 105 until the fastener 405 reaches an end of the channel 410 without a user necessarily continuing to hold the latch 105 in the disengaged position 1000. As a result, the planar faces 230, 235 of the hook 220 and the angled end 225 continue to slide against one another, which generates further corresponding rotation of the member 130 about the fastener 240. The additional rotation of the member 130 disengages the protrusion 245 from both the first locking tab 255 and the second locking tab 260, which enables bidirectional movement of the first rail 110 with respect to the second rail 115 (e.g., in the directions shown by arrow 905).

In one example, upon release of the slide release 125 and the latch 105, the biasing element 205 biases the slide release 125 to return to the locked position 200, while the biasing element 350 biases the latch 105 to return to the home position 700. Thus, for example, slide assembly 100 can be automatically reset to a locked position once a user releases the latch 105 and the slide release 125.

In some implementations, devices or systems disclosed herein can be utilized, manufactured, or installed using methods embodying aspects of the invention. Correspondingly, any description herein of particular features, capabilities, or intended purposes of a device or system is generally intended to include disclosure of a method of using such devices for the intended purposes, a method of otherwise implementing such capabilities, a method of manufacturing relevant components of such a device or system (or the device or system as a whole), and a method of installing disclosed (or otherwise known) components to support such purposes or capabilities. Similarly, unless otherwise indicated or limited, discussion herein of any method of manufacturing or using for a particular device or system, including installing the device or system, is intended to inherently include disclosure, as embodiments of the invention, of the utilized features and implemented capabilities of such device or system.

In this regard, for example, the disclosed technology includes methods for manufacturing and operating a releasable slide assembly (e.g., the slide assembly 100). In some examples, a method can include translating a slide release (e.g., the slide release 125) along a first rail from a locked position to a first position, to partially release a locking member (e.g., the locking member 130) from engagement with a protrusion on a second rail and thereby permit movement of the first rail in one direction relative to the second rail (e.g., to compress the slide assembly 100). While in a home position, a latch secured to the first rail (e.g., the latch 105) can block further translation of the slide release past the first position, while permitting translation of the slide release from the first position back to the locked position. To permit movement of the first rail in two directions relative to the second rail (e.g., to compress or further extend the slide assembly 100), the latch can be rotated away from the home position, e.g., to move a nose of the latch out of alignment with an end of the slide release. This movement of the latch can allow the slide release to then be translated past the first position (and farther away from the locked position), which can further release the locking member from engagement with the protrusion and thereby permit movement of the first rail in two directions relative to the second rail (e.g., to compress or further extend the first rail, including for removal of the first rail from the second rail). In some cases, a user can then release the latch and the slide release so that biasing members can automatically return the latch to the home position and the slide release to the locked position.

Also as used herein, unless otherwise limited or defined, “or” indicates a non-exclusive list of components or operations that can be present in any variety of combinations, rather than an exclusive list of components that can be present only as alternatives to each other. For example, a list of “A, B, or C” indicates options of: A; B; C; A and B; A and C; B and C; and A, B, and C. Correspondingly, the term “or” as used herein is intended to indicate exclusive alternatives only when preceded by terms of exclusivity, such as “either,” “one of,” “only one of,” or “exactly one of.” For example, a list of “one of A, B, or C” indicates options of: A, but not B and C; B, but not A and C; and C, but not A and B. A list preceded by “one or more” (and variations thereon) and including “or” to separate listed elements indicates options of one or more of any or all of the listed elements. For example, the phrases “one or more of A, B, or C” and “at least one of A, B, or C” indicate options of: one or more A; one or more B; one or more C; one or more A and one or more B; one or more B and one or more C; one or more A and one or more C; and one or more of A, one or more of B, and one or more of C. Similarly, a list preceded by “a plurality of” (and variations thereon) and including “or” to separate listed elements indicates options of multiple instances of any or all of the listed elements. For example, the phrases “a plurality of A, B, or C” and “two or more of A, B, or C” indicate options of: A and B; B and C; A and C; and A, B, and C.

As used herein, unless otherwise defined or limited, directional terms are used for convenience of reference for discussion of particular figures or examples. For example, references to downward (or other) directions or top (or other) positions may be used to discuss aspects of a particular example or figure, but do not necessarily require similar orientation or geometry in all installations or configurations.

Also as used herein, unless otherwise limited or defined, “substantially parallel” indicates a direction that is within ±12 degrees of a reference direction (e.g., within ±6 degrees), inclusive.

Also as used herein, unless otherwise limited or defined, “substantially perpendicular” indicates a direction that is within ±12 degrees of perpendicular a reference direction (e.g., within ±6 degrees), inclusive.

Also as used herein, unless otherwise limited or defined, “integral” and derivatives thereof (e.g., “integrally”) describe elements that are manufactured as a single piece without fasteners, adhesive, or the like to secure separate components together. For example, an element stamped, cast, or otherwise molded as a single-piece component from a single piece of sheet metal or using a single mold, without rivets, screws, or adhesive to hold separately formed pieces together is an integral (and integrally formed) element. In contrast, an element formed from multiple pieces that are separately formed initially then later connected together, is not an integral (or integrally formed) element.

Additionally, unless otherwise specified or limited, the terms “about” and “approximately,” as used herein with respect to a reference value, refer to variations from the reference value of ±15% or less, inclusive of the endpoints of the range. Similarly, the term “substantially equal” (and the like) as used herein with respect to a reference value refers to variations from the reference value of less than ±30%, inclusive. Where specified, “substantially” can indicate in particular a variation in one numerical direction relative to a reference value. For example, “substantially less” than a reference value (and the like) indicates a value that is reduced from the reference value by 30% or more, and “substantially more” than a reference value (and the like) indicates a value that is increased from the reference value by 30% or more.

Also as used herein, unless otherwise limited or specified, “substantially identical” refers to two or more components or systems that are manufactured or used according to the same process and specification, with variation between the components or systems that are within the limitations of acceptable tolerances for the relevant process and specification. For example, two components can be considered to be substantially identical if the components are manufactured according to the same standardized manufacturing steps, with the same materials, and within the same acceptable dimensional tolerances (e.g., as specified for a particular process or product).

The previous description of the disclosed embodiments is provided to enable any person skilled in the art to make or use the invention. Given the benefit of this disclosure, various modifications to these embodiments will be readily apparent to those skilled in the art, and the principles defined herein may be applied to other embodiments without departing from the spirit or scope of the invention. Thus, the invention is not intended to be limited to the embodiments shown herein but is to be accorded the widest scope consistent with the principles and novel features disclosed herein.

1. A server slide, comprising:
a first rail;
a second rail that slidably receives the first rail;
a locking member rotatably supported on the first rail to engage a protrusion extending from the second rail;
a slide release that is translatable along the first rail from a locked position to rotate the locking member, to selectively disengage the locking member from the protrusion; and
a latch rotatable relative to a home position to selectively permit translation of the slide release from a first position to a second position;
the slide release being translatable from the locked position into the first position to rotate the locking member, to permit unidirectional movement of the first rail relative to the second rail; and
the slide release being translatable from the first position to the second position to rotate the locking member to permit bidirectional movement of the first rail relative to the second rail.

2. The server slide of claim 1, wherein, in the home position, the latch blocks translation of the slide release from the first position to the second position.

3. The server slide of claim 2, wherein the latch is rotatable from the home position to a disengaged position to permit translation of the slide release from the first position to the second position.

4. The server slide of claim 3, further comprising:
a biasing element arranged between the latch and the first rail, wherein the biasing element biases the latch toward the home position.

5. The server slide of claim 2, wherein, with the latch in the home position, a nose of the latch is aligned with an end of the slide release along a translation direction of the slide release to block translation of the slide release past the first position.

6. The server slide of claim 5, wherein the latch is rotatably secured to the first rail with a first fastener and includes a channel that receives a second fastener to guide rotation of the latch relative to the first fastener.

7. The server slide of claim 1, wherein the locking member includes a first end defining a hook that engages with an angled end of the slide release to rotate the locking member in response to translation of the slide release.

8. The server slide of claim 1, wherein the locking member includes a first locking tab and a second locking tab that abut the protrusion when the slide release is in the locked position, to prevent movement of the first rail in a first direction and a second direction relative to the second rail.

9. The server slide of claim 8, wherein, with the slide release in the first position, the locking member is rotated by a first amount from the locked position to disengage the second locking tab from the protrusion, to permit unidirectional movement of the first rail.

10. The server slide of claim 9, wherein, with the slide release in the second position, the locking member is rotated by a second amount from the locked position to disengage the first locking tab and the second locking tab from the protrusion, to permit bidirectional movement of the first rail.

11. A method of operating a server slide assembly, the method comprising:
translating a slide release along a first rail from a locked position to a first position, to partially release a locking member from engagement with a protrusion on a second rail, to permit movement of the first rail in a first direction relative to the second rail;
rotating a latch away from a home position to permit movement of the slide release into a second position; and
with the latch rotated away from the home position, translating the slide release along the first rail from the locked position or the first position into a second position, to permit selective movement of the first rail relative to the second rail in either of the first direction or a second direction opposite the first direction.

12. The method of claim 11, wherein translating the slide release to the second position releases the locking member from engagement with the protrusion on the second rail to permit bidirectional movement of the first rail relative to the second rail.

13. The method of claim 11, further comprising:
releasing the latch to automatically return the latch to the home position via force from a first biasing member.

14. The method of claim 13, further comprising:
releasing the slide release to automatically return the slide release to the locked position via force from a second biasing member.

15. The method of claim 11, wherein rotating the latch away from the home position includes:
moving a nose of the latch out of alignment with an end of the slide release.

16. The method of claim 11, wherein, in the home position, the latch blocks translation of the slide release from the first position into the second position.

17. A server slide, comprising:
a first rail;
a second rail that slidably receives the first rail;
a locking member rotatably supported on the first rail to engage a protrusion extending from the second rail;
a slide release that is translatable along the first rail to rotate the locking member, to selectively disengage the locking member from the protrusion; and
a latch rotatable relative to a home position to selectively permit translation of the slide release from a first position to a second position, the latch including:
a body, the body defining a nose aligned to contact an end of the slide release when the slide release is in the first position and the latch is in the home position; and
a biasing element secured between the body and the first rail to bias the latch into the home position;
the slide release rotating the locking member to permit unidirectional movement of the first rail relative to the second rail when in the first position; and
the slide release rotating the locking member to permit bidirectional movement of the first rail relative to the second rail when in the second position.

18. The server slide of claim 17, wherein the nose of the latch includes an angled face, and wherein the angled face of the nose contacts an angled face of the slide release when the latch is rotated out of the home position and the slide release is moved towards the second position.

19. The server slide of claim 17, wherein the locking member includes a first end defining a hook that engages with an angled end of the slide release to rotate the locking member in response to translation of the slide release.

20. The server slide of claim 17, wherein the locking member includes a first locking tab and a second locking tab that abut the protrusion when the slide release is in a locked position, to prevent movement of the first rail in a first direction and a second direction relative to the second rail.
